(19) United States
(12) Patent Application Publication
(10) Pub. No.: US 2011/0171469 A1
(43) Pub. Date: Jul. 14, 2011

(54) CNT-INFUSED ARAMID FIBER MATERIALS AND PROCESS THEREFOR

(75) Inventors: Tushar K. SHAH, Columbia, MD (US); Slade H. Gardner, Palo Alto, CA (US); Mark R. Alberding, Glen Arm, MD (US); Harry C. Malecki, Abington, MD (US)

(73) Assignee: Applied NanoStructured Solutions, LLC, Baltimore, MD (US)

(21) Appl. No.: 12/938,328

(22) Filed: Nov. 2, 2010

Related U.S. Application Data
(60) Provisional application No. 61/257,413, filed on Nov. 2, 2009.

(51) Int. Cl. B32B 27/34; B05D 1/36; B05D 1/02; B05D 1/18; C23C 16/00; B05D 3/00; B82Y 99/00; B82Y 40/00

(52) U.S. Cl. 428/395; 427/402; 427/299; 427/249.3; 977/752; 977/750; 977/891

(57) ABSTRACT

A composition includes a carbon nanotube (CNT)-infused aramid fiber material that includes an aramid fiber material of spoolable dimensions, a barrier coating conformally disposed about the aramid fiber material, and carbon nanotubes (CNTs) infused to the aramid fiber material. The infused CNTs are uniform in length and uniform in density. A continuous CNT infusion process includes:(a) disposing a barrier coating and a carbon nanotube (CNT)-forming catalyst on a surface of an aramid fiber material of spoolable dimensions; and (b) synthesizing carbon nanotubes on the aramid fiber material, thereby forming a carbon nanotube-infused aramid fiber material.

This application claims the benefit of U.S. Provisional Application No. 61/257,413, filed on Nov. 2, 2009, which is hereby incorporated by reference herein.

### FIELD OF THE INVENTION

The present invention relates to organic fiber materials, more specifically to aramid fiber materials modified with carbon nanotubes.

### BACKGROUND OF THE INVENTION

Fiber materials are used for many different applications in a wide variety of industries, such as the commercial aviation, recreation, industrial and transportation industries. Commonly-used fiber materials for these and other applications include organic fiber, cellulosic fiber, carbon fiber, metal fiber, ceramic fiber and aramid fiber, for example.

Organic fiber materials, in particular, vary widely in structure and physical properties and application. For example, many elastic organic fiber materials, such as Spandex, are used in the textile/clothing industry. KEVLAR® is a notably strong aramid fiber material present in, for example, body armor and tires, and more generally in numerous composite materials including reinforced resins, such as epoxies, and in cements. Aramid fibers, while having good tensile strength properties, can be sensitive to photo-degradation and can absorb significant moisture.

When incorporating aramid fiber materials into a matrix material to form a composite, sizing can be employed to improve the interface between the aramid fiber material and the matrix. However, conventional sizing agents can exhibit a lower interfacial strength than many aramid fiber materials to which they are applied. As a consequence, the strength of the sizing and its ability to withstand interfacial stress ultimately determines the strength of the overall composite.

It would be useful to develop sizing agents for aramid fiber materials to address some of the issues described above as well as to impart desirable characteristics to the aramid fiber materials. The present invention satisfies this need and provides related advantages as well.

### SUMMARY OF THE INVENTION

In some aspects, embodiments disclosed herein relate to a composition that includes a carbon nanotube (CNT)-infused aramid fiber material which includes an aramid fiber material of spoolable dimensions, a barrier coating conformally disposed about the aramid fiber material; and carbon nanotubes (CNTs) infused to the aramid fiber material. The CNTs are uniform in length and uniform in distribution.

In some aspects, embodiments disclosed herein relate to a continuous CNT infusion process that includes:(a) disposing a barrier coating and a carbon nanotube (CNT)-forming catalyst on a surface of an aramid fiber material of spoolable dimensions; and (b) synthesizing carbon nanotubes on the aramid fiber material, thereby forming a carbon nanotube-infused aramid fiber material.

### BRIEF DESCRIPTION OF THE DRAWINGS

FIG. 1 shows an SEM image of CNTs grown on aramid fiber (Kevlar) at elevated growth temperature to improve thermal and electrical conductivity.

FIG. 2 shows an SEM image of CNTs grown on aramid fiber (Kevlar) at low growth temperature to improve mechanical properties.

FIG. 3 shows a method for producing CNT-infused aramid fiber material in accordance with some embodiments of the present invention.

FIG. 4 shows an apparatus for CNT growth that includes a carbon feed gas pre-heater for low temperature CNT synthesis.

FIG. 5 shows a cross-sectional view of CNT synthesis growth chamber.

FIG. 6 shows a cross-sectional view CNT synthesis growth chamber that includes a carbon feed gas pre-heater and diffuser for low temperature CNT synthesis.

FIG. 7 shows a system for implementing a method for producing CNT-infused aramid fiber material.

FIG. 8 shows another system for implementing a method for producing CNT-infused aramid fiber material, with a subsequent resin coating and winding process.

### DETAILED DESCRIPTION

The present disclosure is directed, in part, to carbon nanotube-infused (“CNT-infused”) aramid fiber materials. The infusion of CNTs to the aramid fiber material can serve many functions including, for example, as a sizing agent to protect against damage from moisture and photo-degradation. A CNT-based sizing can also serve as an interface between the aramid fiber material and a matrix material in a composite. The CNTs can also serve as one of several sizing agents coating the aramid fiber material.

Moreover, CNTs infused on an aramid fiber material can alter various properties of the aramid fiber material, such as thermal and/or electrical conductivity, and/or tensile strength, for example. The processes employed to make CNT-infused aramid fiber materials provide CNTs with substantially uniform length and distribution to impart their useful properties uniformly over the aramid fiber material that is being modified. Furthermore, the processes disclosed herein are suitable for the generation of CNT-infused aramid fiber materials of spoolable dimensions.

The present disclosure is also directed, in part, to processes for making CNT-infused aramid fiber materials. The processes disclosed herein can be applied to nascent aramid fiber materials generated de novo before, or in lieu of, application of a typical sizing solution to the aramid fiber material. Alternatively, the processes disclosed herein can utilize a commercial aramid fiber material, for example, an aramid fiber tow, that already has a sizing applied to its surface. In such embodiments, the sizing can be removed for further processing of the aramid fiber material. The CNTs are synthesized in conjunction with a barrier coating and transition metal nanoparticle either or both of can serve as an intermediate layer providing indirect infusion of the CNTs to the aramid fiber material, as explained further below. After CNT synthesis further sizing agents can be applied to the aramid fiber material as desired.

The processes described herein allow for the continuous production of carbon nanotubes of uniform length and distribution along spoolable lengths of tow, tapes, fabrics and the like. While various mats, woven and non-woven fabrics and the like can be functionalized by processes of the invention, it is also possible to generate such higher ordered structures from the parent tow, yarn or the like after CNT functionalization of these parent materials. For example, a CNT-infused woven fabric can be generated from a CNT-infused aramid fiber tow.

One skilled in the art will recognize the particular challenge posed by processes that grow carbon nanotubes de novo on aramid fibers due to their sensitivity to higher temperatures. For example, KEVLAR® begins to decompose above 400° C. and sublimes at about 450° C. Thus, processes disclosed herein employ one or more techniques to overcome such temperature sensitivity. One technique to overcome temperature sensitivity is to decrease CNT growth times. This can be facilitated by CNT growth reactor configurations which provide rapid CNT growth rates. Another technique is to provide a thermal barrier coating to protect the aramid fiber material during synthesis. Finally, techniques for CNT synthesis at lower temperatures can be utilized. Employing one or more of these techniques can provide CNT-infused aramid fiber materials in a continuous process to provide spoolable quantities of functionalized aramid fiber materials.

As used herein the term “aramid fiber material” refers to any material which has aramid fiber as its elementary structural component. The term encompasses, fibers, filaments, yarns, tows, tapes, woven and non-woven fabrics, plies, mats, 3D woven structures, and pulp.

As used herein the term “spoolable dimensions” refers to aramid fiber materials having at least one dimension that is not limited in length, allowing for the material to be stored on a spool or mandrel. Aramid fiber materials of “spoolable dimensions” have at least one dimension that indicates the use of either batch or continuous processing for CNT infusion as described herein. One aramid fiber material of spoolable dimensions that is commercially available is exemplified by Kevlar® tow with a tex value of 600 (1 tex=1 g/1,000 m) or 550 yard/lb (DuPont, Wilmington, Del.). Commercial aramid fiber tow, in particular, can be obtained on 1, 2, 4, 8 oz, 1, 2, 5, 10, 25 lb. or higher spools, for example. Processes of the invention operate readily with 1 to 10 lb. spools, although larger spools are usable. Moreover, a pre-process operation can be incorporated that divides very large spoolable lengths, for example 50 lb. or more, into easy to handle dimensions, such as two 25 lb spools.

As used herein, the term “carbon nanotube” (CNT, plural CNTs) refers to any of a number of cylindrically-shaped allotropes of carbon of the fullerene family including single-walled carbon nanotubes (SWNTs), double-walled carbon nanotubes (DWNTS), multi-walled carbon nanotubes (MWNTs). CNTs can be capped by a fullerene-like structure or open-ended. CNTs include those that encapsulate other materials.

As used herein “uniform in length” refers to length of CNTs grown in a reactor. “Uniform length” means that the CNTs have lengths with tolerances of plus or minus about 20% of the total CNT length or less, for CNT lengths varying from between about 50 nm to about 200 microns. At very short lengths, such as 50 nm to about 4 microns, this error may be in a range from between about plus or minus 20% of the total CNT length, or even more than about 20% of the total CNT length, such as about 25% of the total CNT length.

As used herein “uniform in distribution” refers to the consistency of density of CNTs on an aramid fiber material. “Uniform distribution” means that the CNTs have a density on the aramid fiber material with tolerances of plus or minus about 10% coverage defined as the percentage of the surface area of the fiber covered by CNTs. This is equivalent to ±1500 CNTs/μm2 for an 8 nm diameter CNT with 5 walls. Such a figure assumes the space inside the CNTs as fillable.

As used herein, the term “infused” means bonded and “infusion” means the process of bonding. Such bonding can involve direct covalent bonding, ionic bonding, pi-pi, and/or van der Waals force-mediated physisorption. Infusion can also involve indirect bonding, such as the indirect CNT infusion to the aramid fiber via bonding to a barrier coating and/or an intervening transition metal nanoparticle disposed between the CNTs and aramid fiber material. The particular manner in which a CNT is “infused” to an aramid fiber material is referred to as a “bonding motif.”

As used herein, the term “transition metal” refers to any element or alloy of elements in the d-block of the periodic table. The term “transition metal” also includes salt forms of the base transition metal element such as oxides, carbides, nitrides, and the like.

As used herein, the term “nanoparticle” or NP (plural NPs), or grammatical equivalents thereof refers to particles sized between about 0.1 to about 100 nanometers in equivalent spherical diameter, although the NPs need not be spherical in shape. Transition metal NPs, in particular, serve as catalysts for CNT growth on the aramid fiber materials.

As used herein, the term “sizing agent,” “fiber sizing agent,” or just “sizing,” refers collectively to materials used in the manufacture of aramid fibers as a coating to protect the integrity of aramid fibers, provide enhanced interfacial interactions between an aramid fiber and a matrix material in a composite, and/or alter and/or enhance particular physical properties of an aramid fiber. In some embodiments, CNTs infused to aramid fiber materials behave as a sizing agent.

As used herein, the term “matrix material” refers to a bulk material than can serve to organize sized CNT-infused aramid fiber materials in particular orientations, including random orientation. The matrix material can benefit from the presence of the CNT-infused aramid fiber material by imparting some aspects of the physical and/or chemical properties of the CNT-infused aramid fiber material to the matrix material.

As used herein, the term “material residence time” refers to the amount of time a discrete point along a aramide fiber material of spoolable dimensions is exposed to CNT growth conditions during CNT infusion processes described herein. This definition includes the residence time when employing multiple CNT growth chambers.

As used herein, the term “linespeed” refers to the speed at which an aramid fiber material of spoolable dimensions can be fed through the CNT infusion processes described herein, where linespeed is a velocity determined by dividing CNT chamber(s) length by the material residence time.

In some embodiments, the present invention provides a composition that includes a carbon nanotube (CNT)-infused aramid fiber material. The CNT-infused aramid fiber material includes an aramid fiber material of spoolable dimensions, a barrier coating conformally disposed about the aramid fiber material, and carbon nanotubes (CNTs) infused to the aramid fiber material. Infusion of CNTs to the aramid fiber material includes a bonding motif of direct bonding of individual CNTs to the aramid fiber, indirect bonding via the transition metal nanoparticle disposed between the CNTs and the aramid fiber, indirect bonding via the transition metal and barrier coating disposed between the CNTs and the aramid fiber, indirect bonding via the barrier coating disposed between the CNTs and aramid fiber, and mixtures thereof.

Without being bound by theory, transition metal NPs, which serve as a CNT-forming catalyst, can catalyze CNT growth by forming a CNT growth seed structure. The CNT-forming catalyst can remain at the base of the aramid fiber material, locked by the barrier coating, and infused to the surface of the aramid fiber material. In such a case, the seed structure initially formed by the transition metal nanoparticle catalyst is sufficient for continued non-catalyzed seeded CNT growth without the catalyst moving along the leading edge of CNT growth, as often observed in the art. In such a case, the NP serves as a point of attachment for the CNT to the aramid fiber material. The presence of the barrier coating can also lead to further indirect bonding motifs. For example, the CNT forming catalyst can be locked into the barrier coating, as described above, but not in surface contact with aramid fiber material. In such a case a stacked structure with the barrier coating disposed between the CNT forming catalyst and aramid fiber material results. In either case, the CNTs formed are infused to the aramid fiber material. Regardless of the nature of the actual bonding motif formed between the carbon nanotubes and the aramid fiber material, the infused CNT is robust and allows the CNT-infused aramid fiber material to exhibit carbon nanotube properties and/or characteristics.

Again, without being bound by theory, when growing CNTs on aramid fiber materials, the elevated temperatures and/or any residual oxygen and/or moisture that can be present in the reaction chamber can damage the aramid fiber material, although measures to minimize such exposure are generally practiced. Moreover, the aramid fiber material itself can be damaged by reaction with the CNT-forming catalyst itself. That is the aramid fiber material can behave as a carbon feedstock to the catalyst at the reaction temperatures employed for CNT synthesis. Such excess carbon can disturb the controlled introduction of the carbon feedstock gas and can even serve to poison the catalyst by overloading it with carbon. The barrier coating employed in the invention is designed to facilitate CNT synthesis on aramid fiber materials. Without being bound by theory, the coating can provide a thermal barrier to heat degradation and can be a physical barrier preventing exposure of the aramid fiber material to the environment at the elevated temperatures. Additionally, the barrier coating can minimize the surface area contact between the CNT-forming catalyst and the aramid fiber material and/or it can mitigate the exposure of the aramid fiber material to the CNT-forming catalyst at CNT growth temperatures.

Compositions having CNT-infused aramid fiber materials are provided in which the CNTs are substantially uniform in length. In the continuous process described herein, the residence time of the aramid fiber material in a CNT growth chamber can be modulated to control CNT growth and ultimately, CNT length. This provides a means to control specific properties of the CNTs grown. CNT length can also be controlled through modulation of the carbon feedstock and carrier gas flow rates and growth temperatures. Additional control of the CNT properties can be obtained by controlling, for example, the size of the catalyst used to prepare the CNTs. For example, 1 nm transition metal nanoparticle catalysts can be used to provide SWNTs in particular. Larger catalysts (>3 nm diameter) can be used to prepare predominantly MWNTs.

Additionally, the CNT growth processes employed are useful for providing a CNT-infused aramid fiber material with uniformly distributed CNTs on aramid fiber materials while avoiding bundling and/or aggregation of the CNTs that can occur in processes in which pre-formed CNTs are suspended or dispersed in a solvent solution and applied by hand to the aramid fiber material. Such aggregated CNTs tend to adhere weakly to an aramid fiber material and the characteristic CNT properties are weakly expressed, if at all. In some embodiments, the maximum distribution density, expressed as percent coverage, that is, the surface area of fiber covered, can be as high as about 55%, assuming about 8 nm diameter CNTs with 5 walls. This coverage is calculated by considering the space inside the CNTs as being “fillable” space. Various distribution/density values can be achieved by varying catalyst dispersion on the surface as well as controlling gas composition and linespeed of the process. Typically for a given set of parameters, a percent coverage within about 10% can be achieved across a fiber surface. Higher density and shorter CNTs are useful for improving mechanical properties, while longer CNTs with lower density are useful for improving thermal and electrical properties, although increased density is still favorable. A lower density can result when longer CNTs are grown. This can be the result of employing higher temperatures and more rapid growth causing lower catalyst particle yields.

The compositions of the invention having CNT-infused aramid fiber materials can include an aramid fiber material such as an aramid filament, an aramid fiber yarn, an aramid fiber tow, an aramid tape, an aramid fiber-braid, a woven aramid fabric, a non-woven aramid fiber mat, and an aramid fiber ply, 3D woven fabrics, and pulps. Aramid fiber can be produced by spinning a solid fiber from a liquid chemical blend with a co-solvent, calcium chloride, to occupy the hydrogen bonds of the amide groups, and N-methyl pyrrolinidone to dissolve the aromatic polymer. Aramid fibers include high aspect ratio fibers having diameters ranging in size from between about 10 microns to about 50 microns. Aramid fiber tows are generally compactly associated bundles of filaments and are usually twisted together to give yarns.

Yarns include closely associated bundles of twisted filaments. Each filament diameter in a yarn is relatively uniform. Yarns have varying weights described by their ‘tex,’ expressed as weight in grams of 1000 linear meters, or denier, expressed as weight in pounds of 10,000 yards, with a typical tex range usually being between about 20 tex to about 1000 tex.

Tows include loosely associated bundles of untwisted filaments. As in yarns, filament diameter in a tow is generally uniform. Tows also have varying weights and the tex range is usually between 20 tex and 1000 tex. They are frequently characterized by the number of thousands of filaments in the tow, for example 1K tow, 5K tow, 10K tow, and the like.

Aramid tapes are materials that can be assembled as weaves or can represent non-woven flattened tows. Aramid tapes can vary in width and are generally two-sided structures similar to ribbon. Processes of the present invention are compatible with CNT infusion on one or both sides of a tape. CNT-infused tapes can resemble a “carpet” or “forest” on a flat substrate surface. Again, processes of the invention can be performed in a continuous mode to functionalize spools of tape.

Aramid fiber-braids represent rope-like structures of densely packed aramid fibers. Such structures can be assembled from yarns, for example. Braided structures can include a hollow portion or a braided structure can be assembled about another core material.

In some embodiments a number of primary aramid fiber material structures can be organized into fabric or sheet-like structures. These include, for example, woven aramid fabrics, non-woven aramid fiber mat and aramid fiber ply, in addition to the tapes described above. Such higher ordered structures can be assembled from parent tows, yarns, filaments or the like, with CNTs already infused in the parent fiber. Alternatively such structures can serve as the substrate for the CNT infusion processes described herein.

Aramid fiber materials are aromatic polyamide structures belonging to the nylon family and exemplified by the well-known KEVLAR® product produced by DuPont. Aramid fiber materials can include the para-aramids, which include commercial products such as KEVLAR®, TECHNORA®, and TWARON®. Other aramid fibers useful in the invention include the meta-aramids such as commercially available NOMEX®, TEIJINCONEX®, KERMEL®, X-FIPER®, and CONEX/NEW STAR®. Another aramid useful aramid is SULFRON®. Aramids useful in the invention can also be formulated as mixture as well, for example, blends of NOMEX® and KEVLAR® are used to make fireproof clothing.

CNTs useful for infusion to aramid fiber materials include single-walled CNTs, double-walled CNTs, multi-walled CNTs, and mixtures thereof. The exact CNTs to be used depends on the application of the CNT-infused aramid fiber. CNTs can be used for thermal and/or electrical conductivity applications, or as insulators. In some embodiments, the infused carbon nanotubes are single-wall nanotubes. In some embodiments, the infused carbon nanotubes are multi-wall nanotubes. In some embodiments, the infused carbon nanotubes are a combination of single-wall and multi-wall nanotubes. There are some differences in the characteristic properties of single-wall and multi-wall nanotubes that, for some end uses of the fiber, dictate the synthesis of one or the other type of nanotube. For example, single-walled nanotubes can be semi-conducting or metallic, while multi-walled nanotubes are metallic.

CNTs lend their characteristic properties such as mechanical strength, low to moderate electrical resistivity, high thermal conductivity, and the like to the CNT-infused aramid fiber material. For example, in some embodiments, the electrical resistivity of a carbon nanotube-infused aramid fiber material is lower than the electrical resistivity of a parent aramid fiber material. The infused CNTs can also provide a degree of protection against photo-degradation by selective absorption of UV radiation by the CNTs in lieu of the aramid fiber materials. More generally, the extent to which the resulting CNT-infused fiber expresses these characteristics can be a function of the extent and density of coverage of the aramid fiber by the carbon nanotubes. Any amount of the fiber surface area, from 0-55% of the fiber can be covered assuming an 8 nm diameter, 5-walled MWNT (again this calculation counts the space inside the CNTs as fillable). This number is lower for smaller diameter CNTs and more for greater diameter CNTs. 55% surface area coverage is equivalent to about 15,000 CNTs/micron2. Further CNT properties can be imparted to the aramid fiber material in a manner dependent on CNT length, as described above. Infused CNTs can vary in length ranging from between about 50 nm to about 500 microns, including 50 nm, 100 nm, 500 nm, 1 micron, 2 microns, 3 microns, 4 micron, 5, microns, 6, microns, 7 microns, 8 microns, 9 microns, 10 microns, 15 microns, 20 microns, 25 microns, 30 microns, 35 microns, 40 microns, 45 microns, 50 microns, 60 microns, 70 microns, 80 microns, 90 microns, 100 microns, 150 microns, 200 microns, 250 microns, 300 microns, 350 microns, 400 microns, 450 microns, 500 microns, and all values in between. CNTs can also be less than about 1 micron in length, including about 0.05 microns, for example. CNTs can also be greater than 500 microns, including for example, 510 microns, 520 microns, 550 microns, 600 microns, 700 microns and all values in between.

Compositions of the invention can incorporate CNTs having a length from about 1 micron to about 10 microns. Such CNT lengths can be useful in application to increase shear strength. CNTs can also have a length from about 0.05-15 microns. Such CNT lengths can be useful in application to increase tensile strength if the CNTs are aligned in the fiber direction. CNTs can also have a length from about 10 microns to about 100 microns. Such CNT lengths can be useful to increase electrical/thermal properties as well as mechanical properties. The process used in the invention can also provide CNTs having a length from about 100 microns to about 150 microns, which can also be beneficial to increase electrical and thermal properties. Such control of CNT length is readily achieved through modulation of carbon feedstock and inert gas flow rates coupled with varying linespeeds and growth temperature as described below. In some embodiments, compositions that include spoolable lengths of CNT-infused aramid fiber materials can have various uniform regions with different lengths of CNTs. For example, it can be desirable to have a first portion of CNT-infused aramid fiber material with uniformly shorter CNT lengths to enhance tensile and shear strength properties, and a second portion of the same spoolable material with a uniform longer CNT length to enhance electrical or thermal properties.

Processes of the invention for CNT infusion to aramid fiber materials allow control of the CNT lengths with uniformity and in a continuous process allowing spoolable aramid fiber materials to be functionalized with CNTs at high rates. With material residence times between 5 to 600 seconds, linespeeds in a continuous process for a system that is 3 feet long can be in a range anywhere from about 0.25 ft/min to about 36 ft/min and greater. The speed selected depends on various parameters as explained further below.

CNT-infused aramid fiber materials of the invention include a barrier coating. Barrier coatings can include for example an alkoxysilane, an alumoxane, alumina nanoparticles, spin on glass and glass nanoparticles. As described below, the CNT-forming catalyst can be added to the uncured barrier coating material and then applied to the aramid fiber material together. In other embodiments the barrier coating material can be added to the aramid fiber material prior to deposition of the CNT-forming catalyst. The barrier coating material can be of a thickness sufficiently thin to allow exposure of the CNT-forming catalyst to the carbon feedstock for subsequent CVD growth. In some embodiments, the thickness is less than or about equal to the effective diameter of the CNT-forming catalyst.

Without being bound by theory, the barrier coating can serve as an intermediate layer between the aramid fiber material and the CNTs and serves to mechanically infuse the CNTs to the aramid fiber material via a locked CNT-forming catalyst nanoparticle that serves as a site CNT growth. Such mechanical infusion provides a robust system in which the aramid fiber material serves as a platform for organizing the CNTs while still imparting properties of the CNTs to the aramid fiber material. Moreover, the benefit of including a barrier coating is the immediate protection it provides the aramid fiber material from chemical damage due to exposure to moisture and any thermal damage due to heating of the aramid fiber material at the temperatures used to promote CNT growth.

The infused CNTs disclosed herein can effectively function as a replacement for conventional aramid fiber “sizing.” The infused CNTs are more robust than conventional sizing materials and can improve the fiber-to-matrix interface in composite materials and, more generally, improve fiber-to-fiber interfaces. Indeed, the CNT-infused aramid fiber materials disclosed herein are themselves composite materials in the sense the CNT-infused aramid fiber material properties will be a combination of those of the aramid fiber material as well as those of the infused CNTs. Consequently, embodiments of the present invention provide a means to impart desired properties to an aramid fiber material that otherwise lack such properties or possesses them in insufficient measure. Aramid fiber materials can be tailored or engineered to meet the requirements of specific applications. The CNTs acting as sizing can protect aramid fiber materials from absorbing moisture due to the hydrophobic CNT structure. Moreover, hydrophobic matrix materials, as further exemplified below, interact well with hydrophobic CNTs to provide improved fiber to matrix interactions.

Despite the useful sizing properties imparted to an aramid fiber material having infused CNTs described above, compositions of the present invention can include further “conventional” sizing agents. Such sizing agents vary widely in type and function and include, for example, surfactants, anti-static agents, lubricants, siloxanes, alkoxysilanes, aminosilanes, silanes, silanols, polyvinyl alcohol, starch, and mixtures thereof. Such secondary sizing agents can be used to protect the CNTs themselves or provide further properties to the fiber not imparted by the presence of the infused CNTs.

Compositions of the present invention can further include a matrix material to form a composite with the CNT-infused aramid fiber material. Such matrix materials can include, for example, an epoxy, a polyester, a vinylester, a polyetherimide, a polyetherketoneketone, a polyphthalamide, a polyetherketone, a polytheretherketone, a polyimide, a phenol-formaldehyde, and a bismaleimide. Matrix materials useful in the present invention can include any of the known matrix materials (see Mel M. Schwartz, Composite Materials Handbook (2d ed. 1992)). Matrix materials more generally can include resins (polymers), both thermosetting and thermoplastic, metals, ceramics, and cements.

Thermosetting resins useful as matrix materials include phthalic/maelic type polyesters, vinyl esters, epoxies, phenolics, cyanates, bismaleimides, and nadic end-capped polyimides (e.g., PMR-15). Thermoplastic resins include polysulfones, polyamides, polycarbonates, polyphenylene oxides, polysulfides, polyether ether ketones, polyether sulfones, polyamide-imides, polyetherimides, polyimides, polyarylates, and liquid crystalline polyester.

Metals useful as matrix materials include alloys of aluminum such as aluminum 6061, 2024, and 713 aluminum braze. Ceramics useful as matrix materials include carbon ceramics, such as lithium aluminosilicate, oxides such as alumina and mullite, nitrides such as silicon nitride, and carbides such as silicon carbide. Cements useful as matrix materials include carbide-base cermets (tungsten carbide, chromium carbide, and titanium carbide), refractory cements (tungsten-thoria and barium-carbonate-nickel), chromium-alumina, nickel-magnesia iron-zirconium carbide. Any of the above-described matrix materials can be used alone or in combination.

In some embodiments the present invention provides a continuous process for CNT infusion that includes (a) disposing a barrier coating and a carbon nanotube-forming catalyst on a surface of an aramid fiber material of spoolable dimensions; and (b) synthesizing carbon nanotubes on the aramid fiber material, thereby forming a carbon nanotube-infused aramid fiber material.

For a 9 foot long system, the linespeed of the process can range from between about 0.25 ft/min to about 108 ft/min. The linespeeds achieved by the process described herein allow the formation of commercially relevant quantities of CNT-infused aramid fiber materials with short production times. For example, at 36 ft/min linespeed, the quantities of CNT-infused aramid fibers (over 1% infused CNTs on fiber by weight) can exceed over 100 pound or more of material produced per day in a system that is designed to simultaneously process 5 separate tows (20 lb/tow). Systems can be made to produce more tows at once or at faster speeds by repeating growth zones.

Moreover, some steps in the fabrication of CNTs, as known in the art, have prohibitively slow rates preventing a continuous mode of operation. For example, in a typical process known in the art, a CNT-forming catalyst reduction step can take 1-12 hours to perform. CNT growth itself can also be time consuming, for example requiring tens of minutes for CNT growth, precluding the rapid linespeeds realized in the present invention. The process described herein overcomes such rate limiting steps.

The CNT-infused aramid fiber material-forming processes of the invention can avoid CNT entanglement that occurs when trying to apply suspensions of pre-formed carbon nanotubes to fiber materials. That is, because pre-formed CNTs are not fused to the aramid fiber material, the CNTs tend to bundle and entangle. The result is a poorly uniform distribution of CNTs that weakly adhere to the aramid fiber material. However, processes of the present invention can provide, if desired, a highly uniform entangled CNT mat on the surface of the aramid fiber material by reducing the growth density. The CNTs grown at low density are infused in the aramid fiber material first. In such embodiments, the fibers do not grow dense enough to induce vertical alignment, the result is entangled mats on the aramid fiber material surfaces. By contrast, manual application of pre-formed CNTs does not insure uniform distribution and density of a CNT mat on the aramid fiber material.

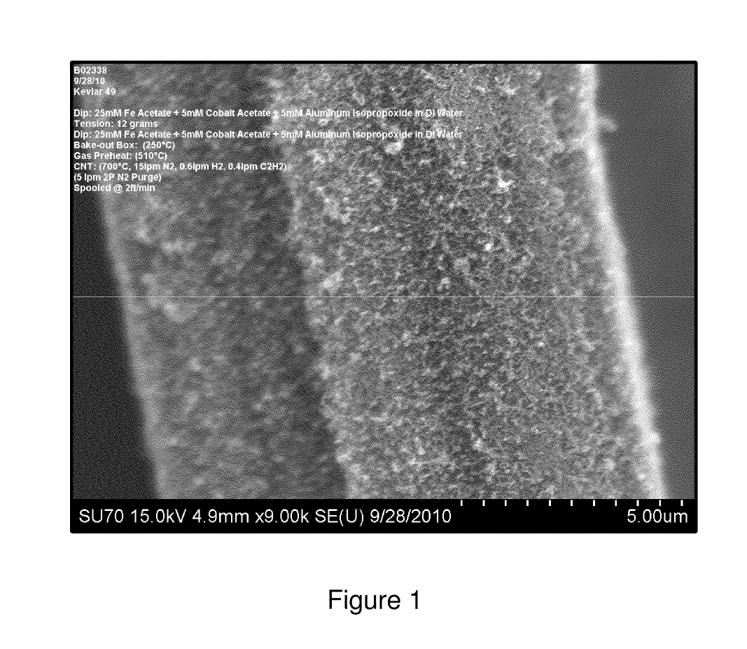

FIG. 1 depicts a flow diagram of method 200 for producing CNT-infused aramid fiber material in accordance with an illustrative embodiment of the present invention.

Process 200 includes at least the operations of:

202: Applying a barrier coating and a CNT-forming catalyst to the aramid fiber material.

204: Heating the aramid fiber material to a temperature that is sufficient for carbon nanotube synthesis.

206: Synthesizing CNTs by CVD-mediated growth on the catalyst-laden aramid fiber.

To infuse carbon nanotubes into an aramid fiber material, the carbon nanotubes are synthesized on the aramid fiber material which is conformally coated with a barrier coating. In one embodiment, this is accomplished by first conformally coating the aramid fiber material with a barrier coating and then disposing nanotube-forming catalyst on the barrier coating, as per operation 202. In some embodiments, the barrier coating can be partially cured prior to catalyst deposition. This can provide a surface that is receptive to receiving the catalyst and allowing it to embed in the barrier coating, including allowing surface contact between the CNT forming catalyst and the aramid fiber material. In such embodiments, the barrier coating can be fully cured after embedding the catalyst. In some embodiments, the barrier coating is conformally coated over the aramid fiber material simultaneously with deposition of the CNT-form catalyst. Once the CNT-forming catalyst and barrier coating are in place, the barrier coating can be fully cured.

In some embodiments, the barrier coating can be fully cured prior to catalyst deposition. In such embodiments, a fully cured barrier-coated aramid fiber material can be treated with a plasma to prepare the surface to accept the catalyst. For example, a plasma treated aramid fiber material having a cured barrier coating can provide a roughened surface in which the CNT-forming catalyst can be deposited. The plasma process for “roughing” the surface of the barrier coating thus facilitates catalyst deposition. The roughness is typically on the scale of nanometers. In the plasma treatment process craters or depressions are formed that are nanometers deep and nanometers in diameter. Such surface modification can be achieved using a plasma of any one or more of a variety of different gases, including, without limitation, argon, helium, oxygen, nitrogen, and hydrogen In order to treat aramid fiber material in a continuous manner, ‘atmospheric’ plasma which does not require vacuum must be utilized. Plasma is created by applying voltage across two electrodes, which in turn ionizes the gaseous species between the two electrodes. A plasma environment can be applied to a aramid fiber substrate in a ‘downstream’ manner in which the ionized gases are flowed down toward the substrate. It is also possible to send the aramid fiber substrate between the two electrodes and into the plasma environment to be treated.

In some embodiments, the aramid fiber can be treated with a plasma environment prior to barrier coating application. For example, a plasma treated aramid fiber material can have a higher surface energy and therefore allow for better wet-out and coverage of the barrier coating. The plasma process can also add roughness to the aramid fiber surface allowing for better mechanical bonding of the barrier coating in the same manner as mentioned above.

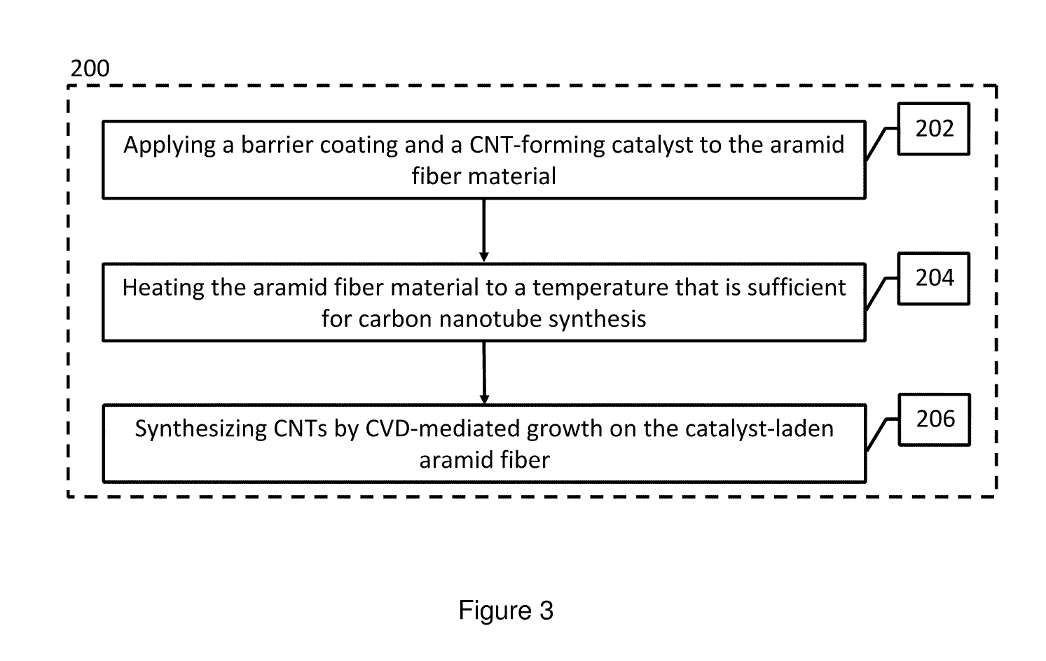

As described further below and in conjunction with FIG. 3, the catalyst is prepared as a liquid solution that contains CNT-forming catalyst that comprise transition metal nanoparticles. The diameters of the synthesized nanotubes are related to the size of the metal particles as described above. In some embodiments, commercial dispersions of CNT-forming transition metal nanoparticle catalyst are available and are used without dilution, in other embodiments commercial dispersions of catalyst can be diluted. Whether to dilute such solutions can depend on the desired density and length of CNT to be grown as described above.

With reference to the illustrative embodiment of FIG. 3, carbon nanotube synthesis is shown based on a chemical vapor deposition (CVD) process and occurs at elevated temperatures. The specific temperature is a function of catalyst choice, but will typically be in a range of about 450 to 1000° C. Accordingly, operation 204 involves heating the barrier-coated aramid fiber material to a temperature in the aforementioned range to support carbon nanotube synthesis.

In operation 206, CVD-promoted nanotube growth on the catalyst-laden aramid fiber material is then performed. The CVD process can be promoted by, for example, a carbon-containing feedstock gas such as acetylene, ethylene, and/or ethanol. The CNT synthesis processes generally use an inert gas (nitrogen, argon, helium) as a primary carrier gas. The carbon feedstock is provided in a range from between about 0% to about 15% of the total mixture. A substantially inert environment for CVD growth is prepared by removal of moisture and oxygen from the growth chamber.

In the CNT synthesis process, CNTs grow at the sites of a CNT-forming transition metal nanoparticle catalyst. The presence of a strong plasma-creating electric field can be optionally employed to affect nanotube growth. That is, the growth tends to follow the direction of the electric field. By properly adjusting the geometry of the plasma spray and electric field, vertically-aligned CNTs (i.e., perpendicular to the aramid fiber material) can be synthesized. Under certain conditions, even in the absence of a plasma, closely-spaced nanotubes will maintain a vertical growth direction resulting in a dense array of CNTs resembling a carpet or forest. The presence of the barrier coating can also influence the directionality of CNT growth.

The operation of disposing a catalyst on the aramid fiber material can be accomplished by spraying or dip coating a solution or by gas phase deposition via, for example, a plasma process. The choice of techniques can be coordinated with the mode with which the barrier coating is applied. Thus, in some embodiments, after forming a solution of a catalyst in a solvent, catalyst can be applied by spraying or dip coating the barrier coated aramid fiber material with the solution, or combinations of spraying and dip coating. Either technique, used alone or in combination, can be employed once, twice, thrice, four times, up to any number of times to provide an aramid fiber material that is sufficiently uniformly coated with CNT-forming catalyst. When dip coating is employed, for example, an aramid fiber material can be placed in a first dip bath for a first residence time in the first dip bath. When employing a second dip bath, the aramid fiber material can be placed in the second dip bath for a second residence time. For example, aramid fiber materials can be subjected to a solution of CNT-forming catalyst for between about 3 seconds to about 90 seconds depending on the dip configuration and linespeed. Employing spraying or dip coating processes, an aramid fiber material with a surface density of catalyst of less than about 5% surface coverage to as high as about 80% coverage, in which the CNT-forming catalyst nanoparticles are nearly monolayer. In some embodiments, the process of coating the CNT-forming catalyst on the aramid fiber material should produce no more than a monolayer. For example, CNT growth on a stack of CNT-forming catalyst can erode the degree of infusion of the CNT to the aramid fiber material. In other embodiments, the transition metal catalyst can be deposited on the aramid fiber material using evaporation techniques, electrolytic deposition techniques, and other processes known to those skilled in the art, such as addition of the transition metal catalyst to a plasma feedstock gas as a metal organic, metal salt or other composition promoting gas phase transport.

Because processes of the invention are designed to be continuous, a spoolable aramid fiber material can be dip-coated in a series of baths where dip coating baths are spatially separated. In a continuous process in which nascent aramid fibers are being generated de novo, dip bath or spraying of CNT-forming catalyst can be the first step after applying and curing or partially curing a barrier coating to the aramid fiber material. Application of the barrier coating and a CNT-forming catalyst can be performed in lieu of application of a sizing, for newly formed aramid fiber materials. In other embodiments, the CNT-forming catalyst can be applied to newly formed aramid fibers in the presence of other sizing agents after barrier coating. Such simultaneous application of CNT-forming catalyst and other sizing agents can still provide the CNT-forming catalyst in surface contact with the barrier coating of the aramid fiber material to insure CNT infusion.

The catalyst solution employed can be a transition metal nanoparticle which can be any d-block transition metal as described above. In addition, the nanoparticles can include alloys and non-alloy mixtures of d-block metals in elemental form or in salt form, and mixtures thereof. Such salt forms include, without limitation, oxides, carbides, and nitrides. Non-limiting exemplary transition metal NPs include Ni, Fe, Co, Mo, Cu, Pt, Au, and Ag and salts thereof and mixtures thereof. In some embodiments, such CNT-forming catalysts are disposed on the aramid fiber by applying or infusing a CNT-forming catalyst directly to the aramid fiber material simultaneously with barrier coating deposition. Many of these transition metal catalysts are readily commercially available from a variety of suppliers, including, for example, Ferrotec Corporation (Bedford, N.H.).

Catalyst solutions used for applying the CNT-forming catalyst to the aramid fiber material can be in any common solvent that allows the CNT-forming catalyst to be uniformly dispersed throughout. Such solvents can include, without limitation, water, acetone, hexane, isopropyl alcohol, toluene, ethanol, methanol, tetrahydrofuran (THF), cyclohexane or any other solvent with controlled polarity to create an appropriate dispersion of the CNT-forming catalyst nanoparticles. Concentrations of CNT-forming catalyst can be in a range from about 1:1 to 1:10000 catalyst to solvent. Such concentrations can be used when the barrier coating and CNT-forming catalyst is applied simultaneously as well.

In some embodiments heating of the barrier coated aramid fiber material can be at a temperature that is between about 450° C. and 750° C. to synthesize carbon nanotubes after deposition of the CNT-forming catalyst. Heating at these temperatures can be performed prior to or substantially simultaneously with introduction of a carbon feedstock for CNT growth, although specific and separate heating conditions for the carbon feedstock and aramid fiber material can be controlled, as explained further below.

In some embodiments, the present invention provides a process that includes removing sizing agents from an aramid fiber material, applying a barrier coating conformally over the aramid fiber material, applying a CNT-forming catalyst to the aramid fiber material, heating the aramid fiber material to at least 450° C., and synthesizing carbon nanotubes on the aramid fiber material. In some embodiments, operations of the CNT-infusion process include removing sizing from an aramid fiber material, applying a barrier coating to the aramid fiber material, applying a CNT-forming catalyst to the aramid fiber, heating the fiber to CNT-synthesis temperature and CVD-promoted CNT growth the catalyst-laden aramid fiber material. Thus, where commercial aramid fiber materials are employed, processes for constructing CNT-infused aramid fibers can include a discrete step of removing sizing from the aramid fiber material before disposing barrier coating and the catalyst on the aramid fiber material.

The step of synthesizing carbon nanotubes can include numerous techniques for forming carbon nanotubes, including those disclosed in co-pending U.S. Patent Application No. US 2004/0245088 which is incorporated herein by reference. The CNTs grown on fibers of the present invention can be accomplished by techniques known in the art including, without limitation, micro-cavity, thermal or plasma-enhanced CVD techniques, laser ablation, arc discharge, and high pressure carbon monoxide (HiPCO). During CVD, in particular, a barrier coated aramid fiber material with CNT-forming catalyst disposed thereon, can be used directly. In some embodiments, any conventional sizing agents can be removed prior to CNT synthesis. In some embodiments, acetylene gas is ionized to create a jet of cold carbon plasma for CNT synthesis. The plasma is directed toward the catalyst-bearing aramid fiber material. Thus, in some embodiments synthesizing CNTs on an aramid fiber material includes (a) forming a carbon plasma; and (b) directing the carbon plasma onto the catalyst disposed on the aramid fiber material. The diameters of the CNTs that are grown are dictated, in part, by the size of the CNT-forming catalyst as described above. To initiate the growth of CNTs, two gases are bled into the reactor: a carrier or process gas such as argon, helium, or nitrogen, and a carbon-containing feedstock gas, such as acetylene, ethylene, ethanol or methane. CNTs grow at the sites of the CNT-forming catalyst.

In some embodiments, the CVD growth is plasma-enhanced. A plasma can be generated by providing an electric field during the growth process. CNTs grown under these conditions can follow the direction of the electric field. Thus, by adjusting the geometry of the reactor vertically aligned carbon nanotubes can be grown radially about a cylindrical fiber. In some embodiments, a plasma is not required for radial growth about the fiber. For aramid fiber materials that have distinct sides such as tapes, mats, fabrics, plies, and the like, catalyst can be disposed on one or both sides and correspondingly, CNTs can be grown on one or both sides as well.

As described above, CNT-synthesis is performed at a rate sufficient to provide a continuous process for functionalizing spoolable aramid fiber materials. Numerous apparatus configurations faciliate such continuous synthesis as exemplified below.

In some embodiments, CNT-infused aramid fiber materials can be constructed in an “all plasma” process. In such embodiments, barrier coated aramid fiber materials pass through numerous plasma-mediated steps to form the final CNT-infused product. The first of the plasma processes, can include a step of fiber surface modification. This is a plasma process for “roughing” the surface of the barrier coating on the aramid fiber material to facilitate catalyst deposition, as described above. As described above, surface modification can be achieved using a plasma of any one or more of a variety of different gases, including, without limitation, argon, helium, oxygen, ammonia, hydrogen, and nitrogen.

After surface modification, the barrier coated aramid fiber material proceeds to catalyst application. This is a plasma process for depositing the CNT-forming catalyst on the fibers. The CNT-forming catalyst is typically a transition metal as described above. The transition metal catalyst can be added to a plasma feedstock gas as a precursor in the form of a ferrofluid, a metal organic, metal salt or other composition for promoting gas phase transport. The catalyst can be applied at room temperature in the ambient environment with neither vacuum nor an inert atmosphere being required. In some embodiments, the aramid fiber material is cooled prior to catalyst application.

Continuing the all-plasma process, carbon nanotube synthesis occurs in a CNT-growth reactor. This can be achieved through the use of plasma-enhanced chemical vapor deposition, wherein carbon plasma is sprayed onto the catalyst-laden fibers. Since carbon nanotube growth occurs at elevated temperatures (typically in a range of about 450 to 750° C. depending on the catalyst), the catalyst-laden fibers can be heated prior to exposing to the carbon plasma. After heating, the aramid fiber material is ready to receive the carbon plasma. The carbon plasma is generated, for example, by passing a carbon containing gas such as acetylene, ethylene, ethanol, and the like, through an electric field that is capable of ionizing the gas. This cold carbon plasma is directed, via spray nozzles, to the aramid fiber material. The aramid fiber material can be in close proximity to the spray nozzles, such as within about 1 centimeter of the spray nozzles, to receive the plasma. In some embodiments, heaters are disposed above the aramid fiber material at the plasma sprayers to maintain the elevated temperature of the aramid fiber material.

Another configuration for continuous carbon nanotube synthesis involves a special rectangular reactor for the synthesis and growth of carbon nanotubes directly on aramid fiber materials. The reactor can be designed for use in a continuous in-line process for producing carbon-nanotube bearing aramid fiber materials. In some embodiments, CNTs are grown via a chemical vapor deposition (“CVD”) process at atmospheric pressure and at elevated temperature in the range of about 450° C. to about 750° C. in a multi-zone reactor. The fact that the synthesis occurs at atmospheric pressure is one factor that facilitates the incorporation of the reactor into a continuous processing line for CNT-on-fiber synthesis. Another advantage consistent with in-line continuous processing using such a zone reactor is that CNT growth occurs in a seconds, as opposed to minutes (or longer) as in other procedures and apparatus configurations typical in the art.

CNT synthesis reactors in accordance with the various embodiments include the following features:

Rectangular Configured Synthesis Reactors: The cross section of a typical CNT synthesis reactor known in the art is circular. There are a number of reasons for this including, for example, historical reasons (cylindrical reactors are often used in laboratories) and convenience (flow dynamics are easy to model in cylindrical reactors, heater systems readily accept circular tubes (quartz, etc.), and ease of manufacturing. Departing from the cylindrical convention, the present invention provides a CNT synthesis reactor having a rectangular cross section. The reasons for the departure are as follows: 1. Since many aramid fiber materials that can be processed by the reactor are relatively planar such as flat tape or sheet-like in form, a circular cross section is an inefficient use of the reactor volume. This inefficiency results in several drawbacks for cylindrical CNT synthesis reactors including, for example, a) maintaining a sufficient system purge; increased reactor volume requires increased gas flow rates to maintain the same level of gas purge. This results in a system that is inefficient for high volume production of CNTs in an open environment; b) increased carbon feedstock gas flow; the relative increase in inert gas flow, as per a) above, requires increased carbon feedstock gas flows. Consider that the volume of a 12K aramid fiber tow is 2000 times less than the total volume of a synthesis reactor having a rectangular cross section. In an equivalent growth cylindrical reactor (i.e., a cylindrical reactor that has a width that accommodates the same planarized aramid fiber material as the rectangular cross-section reactor), the volume of the aramid fiber material is 17,500 times less than the volume of the chamber. Although gas deposition processes, such as CVD, are typically governed by pressure and temperature alone, volume has a significant impact on the efficiency of deposition. With a rectangular reactor there is a still excess volume. This excess volume facilitates unwanted reactions; yet a cylindrical reactor has about eight times that volume. Due to this greater opportunity for competing reactions to occur, the desired reactions effectively occur more slowly in a cylindrical reactor chamber. Such a slow down in CNT growth, is problematic for the development of a continuous process. One benefit of a rectangular reactor configuration is that the reactor volume can be decreased by using a small height for the rectangular chamber to make this volume ratio better and reactions more efficient. In some embodiments of the present invention, the total volume of a rectangular synthesis reactor is no more than about 3000 times greater than the total volume of an aramid fiber material being passed through the synthesis reactor. In some further embodiments, the total volume of the rectangular synthesis reactor is no more than about 4000 times greater than the total volume of the aramid fiber material being passed through the synthesis reactor. In some still further embodiments, the total volume of the rectangular synthesis reactor is less than about 10,000 times greater than the total volume of the aramid fiber material being passed through the synthesis reactor. Additionally, it is notable that when using a cylindrical reactor, more carbon feedstock gas is required to provide the same flow percent as compared to reactors having a rectangular cross section. It should be appreciated that in some other embodiments, the synthesis reactor has a cross section that is described by polygonal forms that are not rectangular, but are relatively similar thereto and provide a similar reduction in reactor volume relative to a reactor having a circular cross section; c) problematic temperature distribution; when a relatively small-diameter reactor is used, the temperature gradient from the center of the chamber to the walls thereof is minimal. But with increased size, such as would be used for commercial-scale production, the temperature gradient increases. Such temperature gradients result in product quality variations across an aramid fiber material substrate (i.e., product quality varies as a function of radial position). This problem is substantially avoided when using a reactor having a rectangular cross section. In particular, when a planar substrate is used, reactor height can be maintained constant as the size of the substrate scales upward. Temperature gradients between the top and bottom of the reactor are essentially negligible and, as a consequence, thermal issues and the product-quality variations that result are avoided. 2. Gas introduction: Because tubular furnaces are normally employed in the art, typical CNT synthesis reactors introduce gas at one end and draw it through the reactor to the other end. In some embodiments disclosed herein, gas can be introduced at the center of the reactor or within a target growth zone, symmetrically, either through the sides or through the top and bottom plates of the reactor. This improves the overall CNT growth rate because the incoming feedstock gas is continuously replenishing at the hottest portion of the system, which is where CNT growth is most active. This constant gas replenishment is an important aspect to the increased growth rate exhibited by the rectangular CNT reactors.

Zoning. Chambers that provide a relatively cool purge zone depend from both ends of the rectangular synthesis reactor. Applicants have determined that if hot gas were to mix with the external environment (i.e., outside of the reactor), there would be an increase in degradation of the aramid fiber material. The cool purge zones provide a buffer between the internal system and external environments. Typical CNT synthesis reactor configurations known in the art typically require that the substrate is carefully (and slowly) cooled. The cool purge zone at the exit of the present rectangular CNT growth reactor achieves the cooling in a short period of time, as required for the continuous in-line processing.

Non-contact, hot-walled, metallic reactor. In some embodiments, a hot-walled reactor is made of metal is employed, in particular stainless steel. This may appear counterintuitive because metal, and stainless steel in particular, is more susceptible to carbon deposition (i.e., soot and by-product formation). Thus, most CNT reactor configurations use quartz reactors because there is less carbon deposited, quartz is easier to clean, and quartz facilitates sample observation. However, Applicants have observed that the increased soot and carbon deposition on stainless steel results in more consistent, faster, more efficient, and more stable CNT growth. Without being bound by theory it has been indicated that, in conjunction with atmospheric operation, the CVD process occurring in the reactor is diffusion limited. That is, the catalyst is “overfed;” too much carbon is available in the reactor system due to its relatively higher partial pressure (than if the reactor was operating under partial vacuum). As a consequence, in an open system—especially a clean one—too much carbon can adhere to catalyst particles, compromising their ability to synthesize CNTs. In some embodiments, the rectangular reactor is intentionally run when the reactor is “dirty,” that is with soot deposited on the metallic reactor walls. Once carbon deposits to a monolayer on the walls of the reactor, carbon will readily deposit over itself. Since some of the available carbon is “withdrawn” due to this mechanism, the remaining carbon feedstock, in the form of radicals, react with the catalyst at a rate that does not poison the catalyst. Existing systems run “cleanly” which, if they were open for continuous processing, would produced a much lower yield of CNTs at reduced growth rates.

Although it is generally beneficial to perform CNT synthesis “dirty” as described above, certain portions of the apparatus, such as gas manifolds and inlets, can nonetheless negatively impact the CNT growth process when soot creates blockages. In order to combat this problem, such areas of the CNT growth reaction chamber can be protected with soot inhibiting coatings such as silica, alumina, or MgO. In practice, these portions of the apparatus can be dip-coated in these soot inhibiting coatings. Metals such as INVAR® can be used with these coatings as INVAR has a similar CTE (coefficient of thermal expansion) ensuring proper adhesion of the coating at higher temperatures, preventing the soot from significantly building up in critical.

Combined Catalyst Reduction and CNT Synthesis. In the CNT synthesis reactor disclosed herein, both catalyst reduction and CNT growth occur within the reactor. This is significant because the reduction step cannot be accomplished timely enough for use in a continuous process if performed as a discrete operation. In a typical process known in the art, a reduction step typically takes 1-12 hours to perform. Both operations occur in a reactor in accordance with the present invention due, at least in part, to the fact that carbon feedstock gas is introduced at the center of the reactor, not the end as would be typical in the art using cylindrical reactors. The reduction process occurs as the fibers enter the heated zone; by this point, the gas has had time to react with the walls and cool off prior to reacting with the catalyst and causing the oxidation reduction (via hydrogen radical interactions). It is this transition region where the reduction occurs. At the hottest isothermal zone in the system, the CNT growth occurs, with the greatest growth rate occurring proximal to the gas inlets near the center of the reactor.

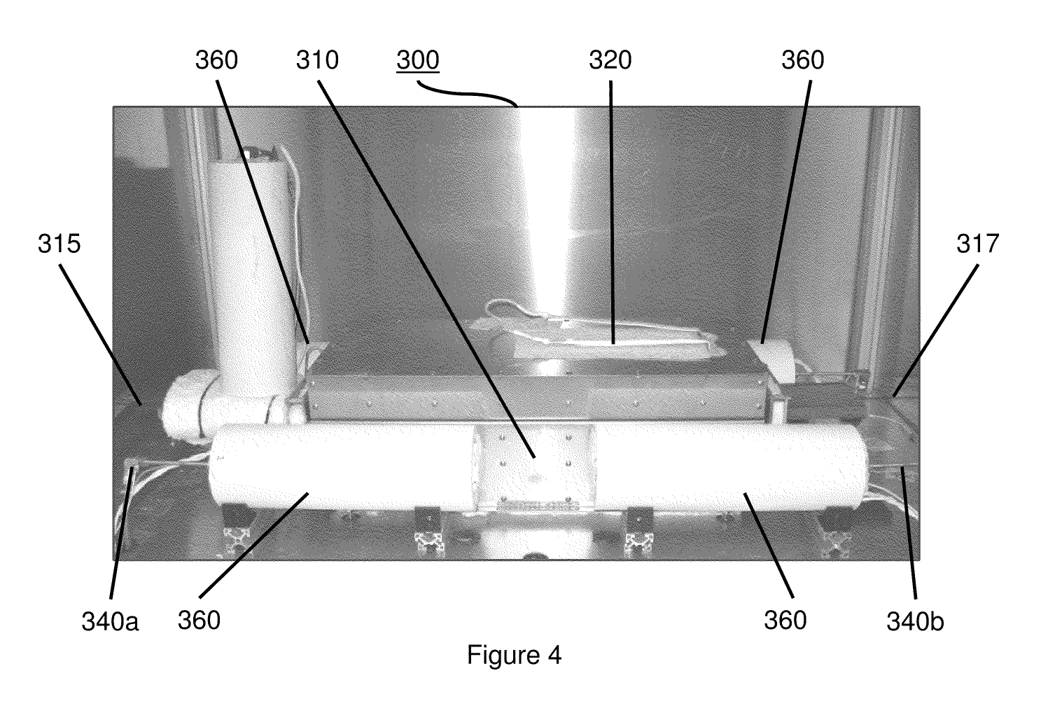

With reference to FIG. 4, there is illustrated a schematic diagram of a system 300 for synthesis of carbon nanotubes using a low temperature process. System 300 includes a growth chamber 310, a heater 320, an aramid fiber material source 330, a carbon feed gas and process or carrier gas source 340, a gas pre-heater 360, and a controller (not shown).

In some embodiments, growth chamber 310 is an open-air continuous operation, flow through reactor. The system can operate at atmospheric pressure, in some embodiments, and at reduced pressures in other embodiments. Growth chamber 310 includes a small volume cavity (not shown) through which an aramid fiber material enters from one end and exits from a second end continuously, thereby facilitating continuous synthesis of carbon nanotubes on the aramid fiber material. An aramid fiber material, such as a tow, for example, allows for a continuous feed of aramid fiber from upstream source 330.

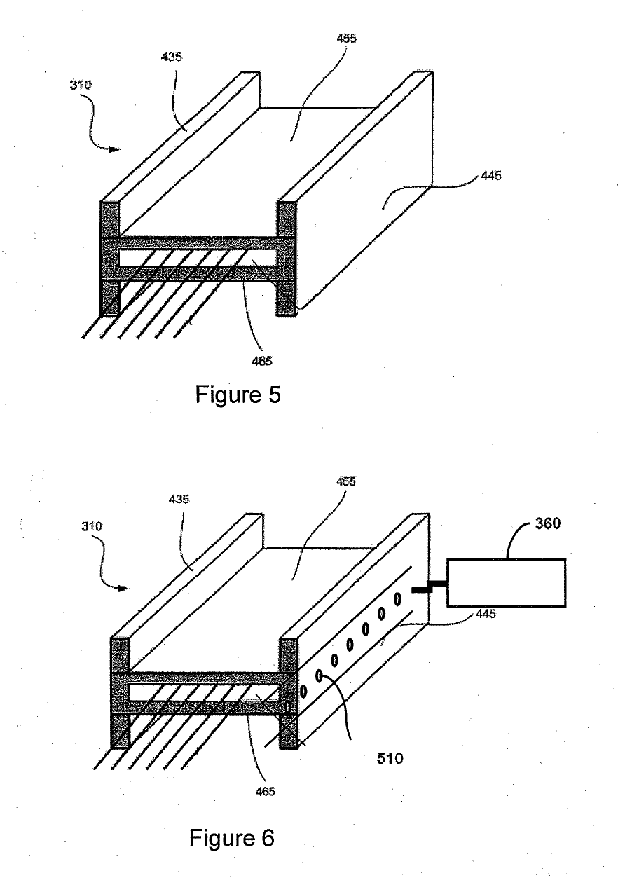

A gas mixture containing a carbon feedstock gas and a process or carrier gas can be continuously fed into the chamber cavity. Growth chamber 310 can be formed by two vertical members 435 and 445 and two horizontal members 455 and 465, arranged in a generally H-shaped configuration, as shown in FIG. 5. Growth chamber 310, has a small cavity volume, as described above to enhance the CNT growth rate. An aramid fiber material with appropriate barrier coating and CNT-forming catalyst passes through the growth chamber at one end at a rate determined by the controller at a first temperature T1 maintained by the controller, or optionally, a separate controller operably-linked to the first controller. Temperature T1 is sufficiently high to allow the growth of carbon nanotubes on the aramid fiber material, but not so high as to adversely impact the physical and chemical properties of the aramid fiber material. The integrity of the fiber can also be protected by the presence of the barrier coating, which can act as a thermal insulator. For example, first temperature T1 can be about 450° C.-650° C. Pre-heated carbon feedstock and any carrier gas is provided at temperature T2, a temperature higher than T1, to facilitate CNT synthesis on the aramid fiber material. After CNT synthesis the aramid fiber material exits growth chamber 310 at the opposite end. From there the CNT-infused aramid fiber material can be subjected to numerous post CNT growth processing steps such as application of sizing agents.

Heater 320 heats the cavity of growth chamber 310 and maintains the operational temperature T1 of the chamber at a pre-set level. In some embodiments, heater 320, controlled by the controller, takes the form of a heating coil contained in each of horizontal members 455 and 465. Because horizontal members 455 and 465 are closely spaced to provide a small volume cavity, the gap through which the aramid fiber material passes is uniformly heated without any significant temperature gradient. Thus, heater 320 heats the surfaces of horizontal members 455 and 465 to provide uniform heating throughout growth chamber 310. In some embodiments, the gap between horizontal members 455 and 465 is between about 1 to 25 mm.

Aramid fiber material source 330 can be adapted to continuously supply the aramid fiber material to growth chamber 310. A typical aramid fiber material can be supplied as a tow, yarn, fabric, or other form as disclosed herein above. Carbon feed gas source 340 is in fluid communication with gas pre-heater 360. Gas pre-heater 360 is thermally isolated from growth chamber 310 to prevent unintentional heating of growth chamber 310. Furthermore, gas pre-heater 360 is thermally insulated from the environment. Gas per-heater 360 can include resistive heat torches, coiled tubes heated inside a resistively heated ceramic heater, induction heating, hot filaments in the gas stream, and infrared heating. In some embodiments, carbon feed gas source 340 and process gas 350 are mixed before the being supplied to pre-heater 360. Carbon feed gas source 340 is heated by pre-heater 360 to temperature T2, such that the carbon feed is dissociated or thermally “cracked” into the requisite free carbon radicals which, in the presence of the CNT-forming catalyst disposed on the aramid fiber material, facilitate CNT growth. In some embodiments, the carbon feed gas source is acetylene and the process gas is nitrogen, helium, argon, or mixtures thereof. Acetylene gas as the carbon feed source obviates the need for a separate process of introducing hydrogen into growth chamber 310 to reduce transition metal nanoparticle catalysts that are in their oxide form. The flow rates of carbon feed gas source 340 and process gas 350 can also be maintained by the controller, or optionally, by another controller operably-linked to the first controller.

It is understood that the controller can be adapted to independently sense, monitor, and control the system parameters as detailed above. The controller can be an integrated, automated computerized system controller that receives parameter data and performs various automated adjustments of control parameters or a manual control arrangement.

In some embodiments, when a carbon feed gas containing acetylene is heated to a temperature T2, which can be between, for example, 450-800° C., and fed into growth chamber 310, the acetylene dissociates into carbon and hydrogen in the presence of the catalyst on the aramid fiber material. The higher temperature T2 facilitates rapid dissociation of acetylene, but because it is heated externally in pre-heater 360, while maintaining chamber temperature at lower temperature T1, the integrity of the aramid fiber material is preserved during CNT synthesis.

FIG. 6 shows an alternate embodiment in which a diffuser 510 is disposed between pre-heater 360 and growth chamber 310. Diffuser 510 provides a uniform distribution of the carbon feed gas and process gas mixture over the aramid fiber material in the growth chamber. In some embodiments, diffuser 510 takes the form of a plate with uniformly distributed apertures for gas delivery. In some embodiments, diffuser 510 extends along a selected section of growth chamber 310. In alternate embodiments, diffuser 510 extends along the entirety of growth chamber 310. Diffuser 510 can be positioned adjacent to growth chamber 310 in a horizontal direction along vertical members 435 and 445 (FIG. 5). In still other embodiments, diffuser 510 is positioned adjacent to growth chamber 310 in a vertical direction along members 455 and 465. In yet another embodiment, diffuser 510 is incorporated into pre-heater 360.

In some embodiments, when loosely affiliated aramid fiber materials, such as a tow are employed, the continuous process can include step that spreads out the strands and/or filaments of the tow. Thus, as a tow is unspooled it can be spread using a vacuum-based fiber spreading system, for example. When employing sized aramid fiber materials, which can be relatively stiff, additional heating can be employed in order to “soften” the tow to facilitate fiber spreading. The spread fibers which comprise individual filaments can be spread apart sufficiently to expose an entire surface area of the filaments, thus allowing the tow to more efficiently react in subsequent process steps. For example, the spread aramid fiber tow can pass through a surface treatment step that is composed of a plasma system and/or barrier coating as described above. The roughened and/or coated, spread fibers then can pass through a CNT-forming catalyst dip bath. The result is fibers of the aramid fiber tow that have catalyst particles distributed radially on their surface. The catalyst-laden fibers of the tow then enter an appropriate CNT growth chamber, such as the rectangular chamber equipped with a gas pre-heater as described above, where a flow through atmospheric pressure CVD or PE-CVD process is used to synthesize the CNTs at rates as high as several microns per second, including between about 0.1 to 10 microns per second. The fibers of the tow, now with radially aligned CNTs, exit the CNT growth reactor.

In some embodiments, CNT-infused aramid fiber materials can pass through yet another treatment process that, in some embodiments is a plasma process used to functionalize the CNTs. Additional functionalization of CNTs can be used to promote their adhesion to particular resins. Thus, in some embodiments, the present invention provides CNT-infused aramid fiber materials having functionalized CNTs.

As part of the continuous processing of spoolable aramid fiber materials, the a CNT-infused aramid fiber material can further pass through a sizing dip bath to apply any additional sizing agents which can be beneficial in a final product. Finally if wet winding is desired, the CNT-infused aramid fiber materials can be passed through a resin bath and wound on a mandrel or spool. The resulting aramid fiber material/resin combination locks the CNTs on the aramid fiber material allowing for easier handling and composite fabrication. In some embodiments, CNT infusion is used to provide improved filament winding. Thus, CNTs formed on aramid fibers such as aramid tow, are passed through a resin bath to produce resin-impregnated, CNT-infused aramid tow. After resin impregnation, the aramid tow can be positioned on the surface of a rotating mandrel by a delivery head. The tow can then be wound onto the mandrel in a precise geometric pattern in known fashion.

The winding process described above provides pipes, tubes, or other forms as are characteristically produced via a male mold. But the forms made from the winding process disclosed herein differ from those produced via conventional filament winding processes. Specifically, in the process disclosed herein, the forms are made from composite materials that include CNT-infused tow. Such forms will therefore benefit from enhanced strength and the like, as provided by the CNT-infused tow. Example III below describes a process for producing a spoolable CNT-infused aramid tow with linespeeds as high as 5 ft/min continuously using the processes described above. In some embodiments, a continuous process for infusion of CNTs on spoolable aramid fiber materials can achieve a linespeed between about 0.25 ft/min to about 9 ft/min. In this embodiment where the system is 3 feet long and operating at a 650° C. growth temperature, the process can be run with a linespeed of about 1 ft/min to about 9 ft/min to produce, for example, CNTs having a length between about 1 micron to about 10 microns. The process can also be run with a linespeed of about 0.5 ft/min to about 1 ft./min to produce, for example, CNTs having a length between about 10 microns to about 50 microns. The process can be run with a linespeed of less than 0.25 ft/min to about 0.5 ft/min to produce, for example, CNTs having a length between about 50 microns to about 100 microns. The CNT length is not tied only to linespeed and growth temperature, however, the flow rate of both the carbon feedstock and the inert carrier gases can also influence CNT length. In some embodiments, more than one carbon material can be run simultaneously through the process. For example, multiple tapes tows, filaments, strand and the like can be run through the process in parallel. Thus, any number of pre-fabricated spools of aramid fiber material can be run in parallel through the process and re-spooled at the end of the process. The number of spooled aramid fiber materials that can be run in parallel can include one, two, three, four, five, six, up to any number that can be accommodated by the width of the CNT-growth reaction chamber. Moreover, when multiple aramid fiber materials are run through the process, the number of collection spools can be less than the number of spools at the start of the process. In such embodiments, aramid yarn, tows, or the like can be sent through a further process of combining such aramid fiber materials into higher ordered aramid fiber materials such as woven fabrics or the like. The continuous process can also incorporate a post processing chopper that facilitates the formation CNT-infused aramid chopped fiber mats, for example.

In some embodiments, processes of the invention allow for synthesizing a first amount of a first type of carbon nanotube on the aramid fiber material, in which the first type of carbon nanotube is selected to alter at least one first property of the aramid fiber material. Subsequently, process of the invention allow for synthesizing a second amount of a second type of carbon nanotube on the aramid fiber material, in which the second type of carbon nanotube is selected to alter at least one second property of the aramid fiber material.

In some embodiments, the first amount and second amount of CNTs are different. This can be accompanied by a change in the CNT type or not. Thus, varying the density of CNTs can be used to alter the properties of the original aramid fiber material, even if the CNT type remains unchanged. CNT type can include CNT length and the number of walls, for example. In some embodiments the first amount and the second amount are the same. If different properties are desirable in this case along the two different stretches of the spoolable material, then the CNT type can be changed, such as the CNT length. For example, longer CNTs can be useful in electrical/thermal applications, while shorter CNTs can be useful in mechanical strengthening applications.

In light of the aforementioned discussion regarding altering the properties of the aramid fiber materials, the first type of carbon nanotube and the second type of carbon nanotube can be the same, in some embodiments, while the first type of carbon nanotube and the second type of carbon nanotube can be different, in other embodiments. Likewise, the first property and the second property can be the same, in some embodiments. For example, the EMI shielding property can be the property of interest addressed by the first amount and type of CNTs and the 2nd amount and type of CNTs, but the degree of change in this property can be different, as reflected by differing amounts, and/or types of CNTs employed. Finally, in some embodiments, the first property and the second property can be different. Again this may reflect a change in CNT type. For example the first property can be mechanical strength with shorter CNTs, while the second property can be electrical/thermal properties with longer CNTs. One skilled in the art will recognize the ability to tailor the properties of the aramid fiber material through the use of different CNT densities, CNT lengths, and the number of walls in the CNTs, such as single-walled, double-walled, and multi-walled, for example.

In some embodiments, processes of the present invention provides synthesizing a first amount of carbon nanotubes on an aramid fiber material, such that this first amount allows the carbon nanotube-infused aramid fiber material to exhibit a second group of properties that differ from a first group of properties exhibited by the aramid fiber material itself. That is, selecting an amount that can alter one or more properties of the aramid fiber material, such as tensile strength. The first group of properties and second group of properties can include at least one of the same properties, thus representing enhancing an already existing property of the aramid fiber material. In some embodiments, CNT infusion can impart a second group of properties to the carbon nanotube-infused aramid fiber material that is not included among the first group of properties exhibited by the aramid fiber material itself.

In some embodiments, a first amount of carbon nanotubes is selected such that the value of at least one property selected from the group consisting of tensile strength, Young's Modulus, shear strength, shear modulus, toughness, compression strength, compression modulus, density, EM wave absorptivity/reflectivity, acoustic transmittance, electrical conductivity, and thermal conductivity of the carbon nanotube-infused aramid fiber material differs from the value of the same property of the aramid fiber material itself.

Tensile strength can include three different measurements: 1) Yield strength which evaluates the stress at which material strain changes from elastic deformation to plastic deformation, causing the material to deform permanently; 2) Ultimate strength which evaluates the maximum stress a material can withstand when subjected to tension, compression or shearing; and 3) Breaking strength which evaluates the stress coordinate on a stress-strain curve at the point of rupture.

Composite shear strength evaluates the stress at which a material fails when a load is applied perpendicular to the fiber direction. Compression strength evaluates the stress at which a material fails when a compressive load is applied.

Multiwalled carbon nanotubes, in particular, have the highest tensile strength of any material yet measured, with a tensile strength of 63 GPa having been achieved. Moreover, theoretical calculations have indicated possible tensile strengths of CNTs of about 300 GPa. Thus, CNT-infused aramid fiber materials, are expected to have substantially higher ultimate strength compared to the parent aramid fiber material. As described above, the increase in tensile strength will depend on the exact nature of the CNTs used as well as the density and distribution on the aramid fiber material. CNT-infused aramid fiber materials can exhibit a doubling in tensile properties, for example. Exemplary CNT-infused aramid fiber materials can have as high as three times the shear strength as the parent unfunctionalized aramid fiber material and as high as 2.5 times the compression strength. Young's modulus is a measure of the stiffness of an isotropic elastic material. It is defined as the ratio of the uniaxial stress over the uniaxial strain in the range of stress in which Hooke's Law holds. This can be experimentally determined from the slope of a stress-strain curve created during tensile tests conducted on a sample of the material.

Electrical conductivity or specific conductance is a measure of a material's ability to conduct an electric current. CNTs with particular structural parameters such as the degree of twist, which relates to CNT chirality, can be highly conducting, thus exhibiting metallic properties. A recognized system of nomenclature(M. S. Dresselhaus, et al. Science of Fullerenes and Carbon Nanotubes, Academic Press, San Diego, Calif. pp. 756-760, (1996)) has been formalized and is recognized by those skilled in the art with respect to CNT chirality. Thus, for example, CNTs are distinguished from each other by a double index (n,m) where n and m are integers that describe the cut and wrapping of hexagonal graphite so that it makes a tube when it is wrapped onto the surface of a cylinder and the edges are sealed together. When the two indices are the same, m=n, the resultant tube is said to be of the “arm-chair” (or n,n) type, since when the tube is cut perpendicular to the CNT axis only the sides of the hexagons are exposed and their pattern around the periphery of the tube edge resembles the arm and seat of an arm chair repeated n times. Arm-chair CNTs, in particular SWNTs, are metallic, and have extremely high electrical and thermal conductivity. In addition, such SWNTs have-extremely high tensile strength.

In addition to the degree of twist CNT diameter also effects electrical conductivity. As described above, CNT diameter can be controlled by use of controlled size CNT-forming catalyst nanoparticles. CNTs can also be formed as semi-conducting materials. Conductivity in multi-walled CNTs (MWNTs) can be more complex. Interwall reactions within MWNTs can redistribute current over individual tubes non-uniformly. By contrast, there is no change in current across different parts of metallic single-walled nanotubes (SWNTs). Carbon nanotubes also have very high thermal conductivity, comparable to diamond crystal and in-plane graphite sheet.

The CNT-infused aramid fiber materials can benefit from the presence of CNTs not only in the properties described above, but can also provide a lighter material in the process. Thus, such lower density and higher strength materials translates to greater strength to weight ratio. It is understood that modifications which do not substantially affect the activity of the various embodiments of this invention are also included within the definition of the invention provided herein. Accordingly, the following examples are intended to illustrate but not limit the present invention.

### EXAMPLE I

This example demonstrates how an aramid fiber material was infused with CNTs in a continuous process to target electrical and thermal property improvements.

In this test trial, the maximum loading of CNTs on fibers was targeted. Kevlar fiber tow with a tex value of 2400 (Du Pont, Wilmington, Del.) was implemented as the aramid fiber substrate. The individual filaments in this aramid fiber tow have a diameter of approximately 17 μm.

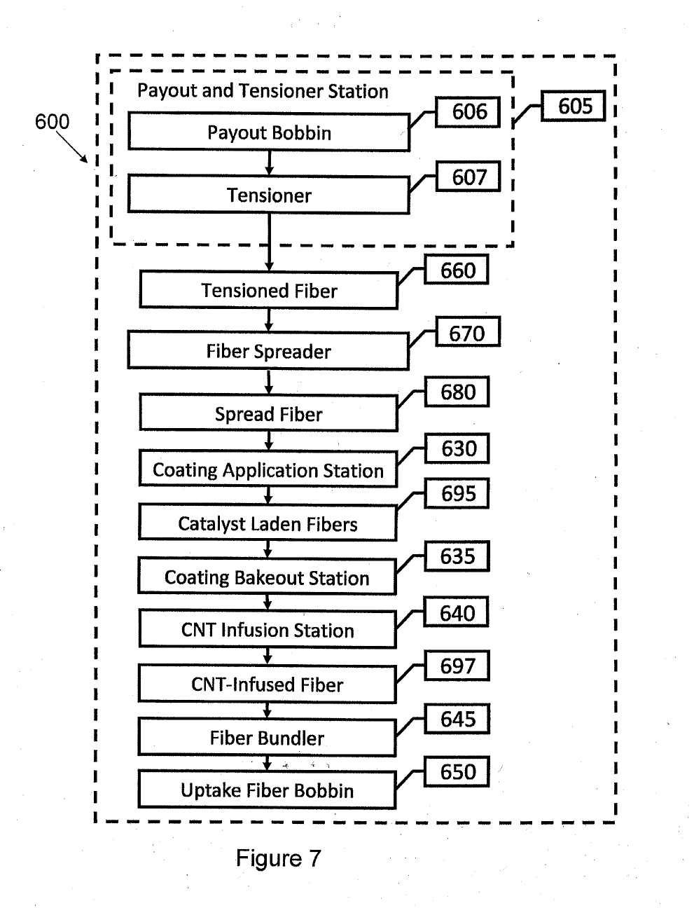

FIG. 7 depicts system 600 for producing CNT-infused fiber in accordance with the illustrative embodiment of the present invention. System 600 included a aramid fiber material payout and tensioner station 605, fiber spreader 670, coating application station 630, coating bakeout station 635, CNT-infusion station 640, fiber bundler station 645, and aramid fiber material uptake bobbin 650, interrelated as shown.

Payout and tension station 605 included payout bobbin 606 and tensioner 607. The payout bobbin delivered aramid fiber material 660 to the process; the fiber was tensioned via tensioner 607. For this example, the aramid fiber was processed at a linespeed of 2.0 ft/min and a tension of 12 grams.

Tensioned fiber material 660 was delivered to fiber spreader 670. The fiber spreader separates the individual elements of the fiber. Various techniques and apparatuses can be used to spread fiber, such as pulling the fiber over and under flat, uniform-diameter bars, or over and under variable-diameter bars, or over bars with radially-expanding grooves and a kneading roller, over a vibratory bar, etc. Spreading the fiber enhances the effectiveness of downstream operations, such as plasma application, barrier coating application, and catalyst application, by exposing more fiber surface area.

Payout and tension station 605 and fiber spreader station 670 are routinely used in the fiber industry; those skilled in the art will be familiar with their design and use.

Spread fiber 680 was delivered to catalyst application station 630. In this test trial, a multi-compound metal salt catalyst coating solution was employed in a dip coating configuration. The solution was 25 mM iron acetate, 5 mM cobalt acetate, and 5 mM aluminum nitrate diluted in dionized mater. The catalyst coating was applied at room temperature in the ambient environment.

Catalyst laden aramid fibers 695 were delivered to catalalyst bakeout station 635 for drying of the nanoscale catalyst coating. The bakeout station consisted of a heated oven used to remove water from the entire aramid fiber at a temperature of 250° C.

After bakeout, catalyst-laden fiber 695 was finally advanced to CNT-infusion station 640. In this trial, a rectangular reactor with a 24 inch long growth zone was used to employ CVD growth at atmospheric pressure. 93.3% of the total gas flowwas inert gas (Nitrogen), 4.0% was hydrogen gas, and 2.7% was the carbon feedstock (acetylene). The growth zone was a gradient temperature along the chamber length with the maximum temperature at the chamber center held at 700° C. The incoming gas temperature is also preheated to 510° C. The resulting CNT growth is shown in FIG. 1, which represents just under 2% CNTs by weight of the fiber.

After CNT-infusion, CNT-infused fiber 697 was re-bundled at fiber bundler station 645. This operation recombined the individual strands of the fiber, effectively reversing the spreading operation that was conducted at station 610.

The bundled, CNT-infused fiber 697 was wound about uptake fiber bobbin 650 for storage. CNT-infused fiber 697 was loaded with matted CNTs approximately 0.5-3 μm in length and was then ready for use in composite materials with enhanced electrical and thermal properties.

### EXAMPLE II

This example shows how an aramid fiber material can be infused with CNTs in a continuous process to target mechanical property improvements such as interlaminar shear strength.

In this test trial, a minimum loading of CNTs on fibers as well as low process temperatures is targeted. Kevlar fiber tow with a tex value of 2400 (Du Pont, Wilmington, Del.) is implemented as the aramid fiber substrate. The individual filaments in this aramid fiber tow have a diameter of approximately 17 μm.

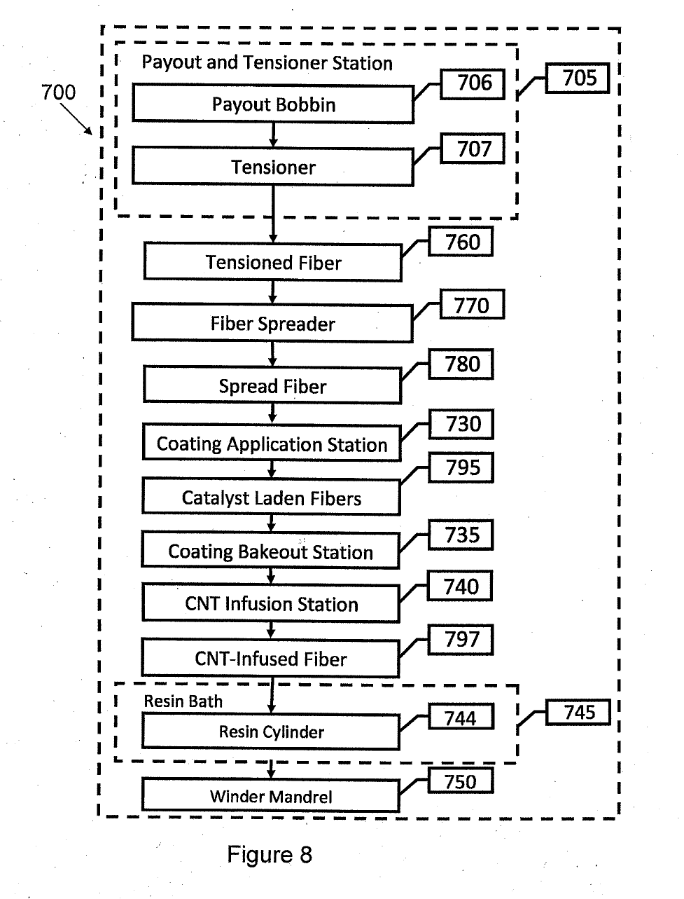

FIG. 8 depicts system 700 for producing CNT-infused fiber in accordance with the illustrative embodiment of the present invention. System 700 included a aramid fiber material payout and tensioner station 705, fiber spreader station 770, coating application station 730, coating baekout station 735, CNT-infusion station 740, resin bath 745, and winder mandrel 750 interrelated as shown.

Payout and tension station 705 included payout bobbin 706 and tensioner 707. The payout bobbin delivered aramid fiber material 760 to the process; the fiber was tensioned via tensioner 707. For this example, the aramid fiber was processed at a linespeed of 1.0 ft/min and a tension of 10 grams.

Fiber material 760 was delivered to fiber spreader 770. The fiber spreader separated the individual elements of the fiber. Various techniques and apparatuses can be used to spread fiber, such as pulling the fiber over and under flat, uniform-diameter bars, or over and under variable-diameter bars, or over bars with radially-expanding grooves and a kneading roller, over a vibratory bar, etc. Spreading the fiber enhances the effectiveness of downstream operations, such as plasma application, barrier coating application, and catalyst application, by exposing more fiber surface area.

Payout and tension station 705 and fiber spreader station 770 are routinely used in the fiber industry; those skilled in the art will be familiar with their design and use.

Spread fiber 780 was delivered to catalyst application station 730. In this trial, a multi-compound metal salt catalyst coating solution was employed in a dip coating configuration. The solution was 50 mM iron acetate, 20 mM cobalt acetate, and 10 mM aluminum nitrate diluted in dionized mater. The catalyst coating was applied at room temperature in the ambient environment.

Catalyst laden aramid fibers 795 were delivered to catalalyst bakeout station 735 for drying of the nanoscale catalyst coating. The bakeout station consisted of a heated oven used to remove water across the entire aramid fiber at a temperature of 200° C.

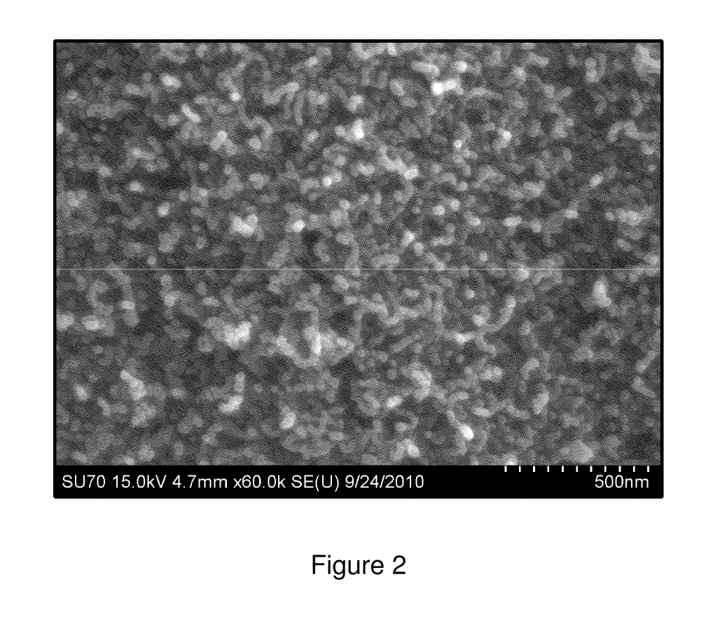

After bakeout, catalyst-laden fiber 795 was finally advanced to CNT-infusion station 740. In this example, a rectangular reactor with a 24 inch long growth zone was used to employ CVD growth at atmospheric pressure. 90.0% of the total gas flow was inert gas (Nitrogen), 8.0% was hydrogen gas, and 2.0% was the carbon feedstock (acetylene). The growth zone was a gradient temperature along the chamber length with the maximum temperature at the chamber center held at 600° C. The incoming gas temperature was also preheated to 600° C. The resulting CNT growth is shown in FIG. 2, which represents just under 1% CNTs by weight of the fiber.

After CNT growth, wound CNT-infused fiber 797 were delivered to resin bath 745. The resin bath contained resin for the production of a composite material comprising the CNT-infused fiber and the resin. This resin included EPON 862 epoxy resin.

Resin bath 745 was implemented as a doctor blade roller bath wherein a polished rotating cylinder (e.g., cylinder 744) that was disposed in the bath picked up resin as it turned. The doctor bar (not depicted in FIG. 8) pressed against the cylinder to obtain a precise resin film thickness on cylinder 744 and pushed excess resin back into the bath. As the aramid fiber roving 797 was pulled over the top of cylinder 744, it contacted the resin film and weted out.

After leaving resin bath 745, resin-wetted, CNT-infused fibers 797 were passed through various rings, eyelets and, typically, a multi-pin “comb” (not depicted) that was disposed behind a delivery head (not depicted). The comb kept the aramid fibers 797 separated until they were brought together in a single combined band on rotating winder mandrel 750. The mandrel acted as a mold for a structure requiring composites material with improved mechanical strength in particular interlaminar shear strength. CNTs grown using the above described process were less than 1 micron in length.

It is to be understood that the above-described embodiments are merely illustrative of the present invention and that many variations of the above-described embodiments can be devised by those skilled in the art without departing from the scope of the invention. For example, in this Specification, numerous specific details are provided in order to provide a thorough description and understanding of the illustrative embodiments of the present invention. Those skilled in the art will recognize, however, that the invention can be practiced without one or more of those details, or with other processes , materials, components, etc.

Furthermore, in some instances, well-known structures, materials, or operations are not shown or described in detail to avoid obscuring aspects of the illustrative embodiments. It is understood that the various embodiments shown in the Figures are illustrative, and are not necessarily drawn to scale. Reference throughout the specification to “one embodiment” or “an embodiment” or “some embodiments” means that a particular feature, structure, material, or characteristic described in connection with the embodiment(s) is included in at least one embodiment of the present invention, but not necessarily all embodiments. Consequently, the appearances of the phrase “in one embodiment,” “in an embodiment,” or “in some embodiments” in various places throughout the Specification are not necessarily all referring to the same embodiment. Furthermore, the particular features, structures, materials, or characteristics can be combined in any suitable manner in one or more embodiments. It is therefore intended that such variations be included within the scope of the following claims and their equivalents.

What is claimed is:

1. A composition comprising a carbon nanotube (CNT)-infused aramid fiber material comprising an aramid fiber material of spoolable dimensions, a barrier coating conformally disposed about the aramid fiber material and carbon nanotubes (CNTs) infused to the aramid fiber material, wherein said CNTs are uniform in length and uniform in distribution.

2. The composition of claim 1 further comprising transition metal nanoparticles used in the growth of said CNTs.

3. The composition of claim 1, wherein the infusion of CNTs to the aramid fiber material comprises a bonding motif selected from direct bonding of individual CNTs to the aramid fiber, indirect bonding via the transition metal nanoparticle disposed between the CNTs and the aramid fiber, indirect bonding via the transition metal and barrier coating disposed between the CNTs and the aramid fiber, indirect bonding via the barrier coating disposed between the CNTs and aramid fiber, and mixtures thereof.

4. The composition of claim 1, where said CNTs have a length of about 50 nm micron to about 500 microns.

5. The composition of claim 1, wherein said CNTs have a length from about 1 micron to about 10 microns.

6. The composition of claim 1, wherein said CNTs have a length from about 10 microns to about 100 microns.

7. The composition of claim 1, wherein said CNTs have a length from about 100 microns to about 500 microns.

8. The composition of claim 1, wherein said uniformity of distribution is characterized by a density up to about 15,000 nanotubes per micron squared (μm²).

9. The composition of claim 1, wherein said aramid fiber material is selected from a carbon filament, an aramid tow, an aramid yarn, an aramid tape, a unidirectional aramid tape, an aramid fiber-braid, a woven aramid fabric, a non-woven aramid fiber mat, and an aramid fiber ply.

10. The composition of claim 1, wherein said CNTs are selected from the group consisting of single-walled CNTs, double-walled CNTs, multi-walled CNTs, and mixtures thereof.

11. The composition of claim 1, wherein said CNTs are multi-walled CNTs.

12. The composition of claim 1 further comprising a sizing agent selected from a surfactant, an anti-static agent, a lubricant, siloxanes, alkoxysilanes, aminosilanes, silanes, silanols, polyvinyl alcohol, starch, and mixtures thereof.

13. The composition of claim 1 further comprising a matrix material selected from an epoxy, a polyester, a vinylester, a polyetherimide, a polyetherketoneketone, a polyphthalamide, a polyetherketone, a polytheretherketone, a polyimide, a phenol-formaldehyde, and a bismaleimide.

14. The composition of claim 1, wherein the electrical resistivity of said carbon nanotube-infused aramid fiber is lower than the electrical resistivity of said aramid fiber.

15. A continuous CNT infusion process comprising:
(a) disposing a barrier coating and a carbon nanotube (CNT)-forming catalyst on a surface of an aramid fiber material of spoolable dimensions; and
(b) synthesizing carbon nanotubes on said aramid fiber material, thereby forming a carbon nanotube-infused aramid fiber material;
wherein said continuous CNT infusion process has a material residence time of between about 5 to about 600 seconds in a CNT growth chamber.

16. The process of claim 15, wherein a material residence time of about 5 to about 120 seconds produces CNTs having a length between about 1 micron to about 10 microns.

17. The process of claim 15, wherein a material residence time of about 120 to about 300 seconds produces CNTs having a length between about 10 microns to about 50 microns.

18. The process of claim 15, wherein a material residence time of about 300 to about 600 seconds produces CNTs having a length between about 50 microns to about 200 microns.

19. The process of claim 15, wherein more than one aramid material is run simultaneously through the process.

20. The process of claim 15 further comprising removing a sizing material from said aramid fiber material before disposing said barrier coating or catalyst on said aramid fiber.

21. The process of claim 15 wherein said CNT-forming catalyst is an iron-based nanoparticle catalyst.

22. The process of claim 15, wherein the operation of disposing said CNT-forming catalyst on said aramid fiber material comprises spraying, dip coating, or gas phase deposition onto said aramid fiber material with said solution.

23. The process of claim 15, wherein the operation of disposing said barrier coating is simultaneous with disposing said CNT-forming catalyst on said aramid fiber material.

24. The process of claim 15, wherein said barrier coating is conformally disposed on said aramid fiber material just prior to disposing said CNT-forming catalyst on said aramid fiber material.

25. The process of claim 24 further comprising partially curing said barrier coating prior to disposing said CNT-forming catalyst on said aramid fiber material.

26. The process of claim 25 further comprising curing the barrier coating after disposing said CNT-forming catalyst on said aramid fiber material.

27. The process of claim 15, wherein the step of synthesizing carbon nanotubes comprises CVD growth.

28. The process of claim 15 further comprising applying sizing to said carbon nanotube-infused aramid fiber material.

29. The process of claim 15 further comprising applying a matrix material to said carbon nanotube-infused aramid fiber.

30. The process of claim 15 further comprising: a) synthesizing a first amount of a first type of carbon nanotube on said aramid fiber material, wherein said first type of carbon nanotube is selected to alter at least one first property of said aramid fiber material; and b) synthesizing a second amount of a second type of carbon nanotube on said aramid fiber material, wherein said second type of carbon nanotube is selected to alter at least one second property of said aramid fiber material.

31. The process of claim 30, wherein said first amount and said second amount are different.

32. The process of claim 30, wherein said first amount and said second amount are the same.

33. The process of claim 30, wherein said first type of carbon nanotube and said second type of carbon nanotube are the same.

34. The process of claim 30, wherein said first type of carbon nanotube and said second type of nanotube are different.

35. The process of claim 30, wherein said first property and said second property are the same.

36. The process of 30, wherein said first property and said second property are different.

37. The process of claim 30, wherein said at least one first property and at least one second property are independently selected from the group consisting of tensile strength, Young's Modulus, shear strength, shear modulus, toughness, compression strength, compression modulus, density, EM wave absorptivity/reflectivity, acoustic transmittance, electrical conductivity, and thermal conductivity.
